(19) United States
(12) Patent Application Publication
(10) Pub. No.: US 2025/0251449 A1
(43) Pub. Date: Aug. 7, 2025

(54) INNOVATIVE SRAM IN-SILICON MONITOR CIRCUIT AND SYSTEM IMPLEMENTATION

(71) Applicant: NVIDIA Corporation, Santa Clara, CA (US)

(72) Inventors: Helen Gong, Sunnyvale, CA (US); Shiming Chen, Union City, CA (US); Lei Wang, San Jose, CA (US); Spencer Gold, Pepperell, MA (US); Manish Patel, Bangalore (IN); Hank Lin, Palo Alto, CA (US); Andreas Gotterba, Santa Clara, CA (US); Chen Lu, San Jose, CA (US); Karthik Natarajan, Fremont, CA (US)

(21) Appl. No.: 18/434,283

(22) Filed: Feb. 6, 2024

(51) Int. Cl. G01R 31/3185; G01R 31/317

(52) U.S. Cl. CPC G01R 31/318597; G01R 31/31718; G01R 31/318594

(57) ABSTRACT

An in-silicon monitoring circuit for an on-chip static RAM (SRAM) is disclosed. In one embodiment, the on-chip static RAM comprises a clock generation unit and an SRAM ring oscillator (RAMRO) output circuit. In one embodiment, the clock generation unit includes a multiplexer with inputs that include a clock signal a reset signal provided by a delay chain of the SRAM, where the multiplexer is controlled by an enable signal (RAMRO_EN). In one embodiment, the RAMRO output circuit that generates a RAMRO output signal (RAM_RO) based on the RAMRO_EN signal and an input from the delay chain of the SRAM when the RAMRO_EN signal is asserted, where the RAMRO output signal correlates to electrical characteristics of semiconductor material upon which the SRAM is located.

### TECHNICAL FIELD

This application is directed, in general, to in-silicon monitors and, more specifically, to in-silicon monitors monitoring on-chip static RAMs (SRAMs).

### BACKGROUND

With increased silicon wafer diameters, e.g., 300 mm wafers, variation of process, voltage, and temperature (PVT) across a silicon wafer is significant enough to cause performance characteristics, e.g., speed, power, etc., of individual integrated circuits (ICs), or dies, on the silicon wafer to vary such that some ICs will carry a higher value than others or, in the worst case, that performance characteristics of some ICs will be below acceptable levels. As such, semiconductor manufacturers and designers desire to have a method to identify specific ICs on the wafer with differing performance characteristics in order to be able to classify performance of the ICs on the silicon wafer in a process sometimes termed “binning,” which includes identifying those ICs with performance characteristics that are of higher value and those ICs with performance characteristics that do not meet minimum acceptable levels.

Many of today's ICs are relatively large in die area and include, inter alia, multiple processing units (e.g., general purpose processing units (e.g., CPUs), specific graphics processing units (e.g., GPUs), etc.), large blocks of logic functions, memory circuits including SRAMs, analog circuitry, etc. In many cases, these ICs are termed a “system-on-a-chip” (SOCs). Semiconductor manufacturers and designers include specific circuitry in order to measure performance characteristics of ICs, or SOCs, on a silicon wafer as noted above. Typically, this specific circuitry comprises a ring oscillator (RO) which is used to measure a specific performance characteristic, i.e., speed of silicon local to the IC, e.g., SOC.

One implementation of a RO is a series of inverters. With a known number of inverters, semiconductor manufacturers and designers can expect a nominal time delay from a signal being input to the RO, e.g., the known number of inverters, to a signal output from the RO based on, e.g., the known number of inverters, and a nominal PVT expected for the silicon wafer. The PVT variance of the silicon wafer could be such that there is a measurable difference of silicon performance within each specific die or IC. When the PVT varies across the wafer, a time delay of the RO (e.g., the difference from the input signal and the output signal) will vary across the wafer. By including a RO in the IC, time delays from each specific IC can be determined for that specific circuit and the specific IC can be “binned out,” e.g., categorized, based on the time delay measured by the RO of each specific IC. Moreover, for large ICs with the potential for measurable PVT variance intra-chip, more than one instance of a RO can be placed at various locations on the IC to determine performance at multiple locations on the die or IC. Thus, ICs with higher performance, e.g., faster speed, can be identified, ICs with acceptable levels of performance, e.g., speed, can be identified, and ICs with below acceptable levels of performance can be identified.

### SUMMARY OF THE DISCLOSURE

In one aspect, an in-silicon monitoring circuit for an on-chip static RAM (SRAM) is disclosed. In one embodiment, the in-silicon monitoring circuit comprises a clock generation unit, a ring oscillator (RAMRO), and a RAMRO output circuit. In one embodiment, the clock generation unit includes a logic function and a multiplexer. In one embodiment, the logic function has inputs that include at least a clock signal for the SRAM, a clock enable signal, and a reset signal. In one embodiment, the multiplexer has inputs that include an output from the logic function circuit and the reset signal, where the multiplexer is controlled by an enable signal (RAMRO_EN). In one embodiment, the RAMRO comprise a delay chain of the SRAM which includes at least a plurality of inverters, logic circuitry, at least one replica bit cell circuit, and associated wire traces where an input to the delay chain is an output of the multiplexer of the clock generation unit. In one embodiment, the RAMRO output circuit generates a RAMRO output signal (RAM_RO) based on the RAMRO_EN signal and an input from the RAMRO when the RAMRO_EN signal is asserted where the RAMRO output signal correlates to electrical characteristics of semiconductor material upon with the SRAM is located.

In another aspect, a method of determining electrical characteristics of semiconductor material upon which an SRAM on a die is located is disclosed. In one embodiment, the method comprises feeding back a clock signal from an output of a ring oscillator of the SRAM (RAMRO) to the input of the RAMRO, counting pulses of the clock signal output from the RAMRO of the SRAM (RAM_RO output signal), correlating the count of pulses of the clock signal output from the delay chain of the SRAM (RAM_RO output signal) with electrical characteristics of the semiconductor material upon which the SRAM on the die is located, and binning out die based on the electrical characteristics of the semiconductor material upon which the SRAM on the die is located. In one embodiment, the RAMRO comprises a delay chain of the SRAM which includes at least a plurality of inverters, logic circuity, at least one replica bit cell circuit, and associated wire traces.

In another aspect, an integrated circuit (IC) is disclosed. In one embodiment, the IC comprises at least one processing unit and at least one static random-access memory (SRAM) communicatively coupled to the at least one processing unit. In one embodiment, the SRAM includes an in-silicon monitoring circuit, the in-silicon monitoring circuit including a clock generation unit, a ring oscillator of the SRAM (RAMRO), and a RAMRO output circuit. In one embodiment, the clock generation unit comprises a logic function circuit and a multiplexer. In one embodiment, the logic function has inputs that include at least a clock signal for the at least one SRAM, a clock enable signal, and a reset signal. In one embodiment, multiplexer has inputs that include an output from the logic function circuit and the reset signal, where the multiplexer is controlled by an enable signal (RAMRO_EN). In one embodiment, the RAMRO comprises a delay chain which includes at least a plurality of inverters, logic circuity, at least one replica bit cell circuit, and associated wire traces where an input to the delay chain is an output of the multiplexer of the clock generation unit. In one embodiment, the RAMRO output circuit generates a RAMRO output signal (RAM_RO) based on the RAMRO_EN signal and an input from the delay chain when the RAMRO_EN signal is asserted where the RAMRO output signal correlates to electrical characteristics of semiconductor material upon which the SRAM is located.

In another aspect, a library of circuit designs is disclosed. In one embodiment, the library comprises a design for an in-silicon monitoring circuit for an on-chip static RAM (SRAM). In one embodiment, the in-silicon monitoring circuit includes a clock generation unit, a ring oscillator of the SRAM (RAMRO), and a RAMRO output circuit. In one embodiment, the clock generation unit comprises a logic function and a multiplexer. In one embodiment, the logic function has inputs that include at least a clock signal for the SRAM, a clock enable signal, and a reset signal. In one embodiment, the multiplexer has inputs that include an output from the logic function circuit and the reset signal, where the multiplexer is controlled by an enable signal (RAMRO_EN). In one embodiment, the RAMRO comprises a delay chain which includes at least a plurality of inverters, logic circuity, at least one replica bit cell circuit, and associated wire traces, where an input to the delay chain is an output of the multiplexer of the clock generation unit. In one embodiment, the RAMRO output circuit that generates a RAMRO output signal (RAM_RO) based on the RAMRO_EN signal and an input from the delay chain, where the RAMRO output signal correlates to electrical characteristics of semiconductor material upon which the SRAM is located.

In another aspect, an in-silicon monitoring circuit for an on-chip static RAM (SRAM) is disclosed. In one embodiment, the on-chip static RAM comprises a clock generation unit and an SRAM ring oscillator (RAMRO) output circuit. In one embodiment, the clock generation unit includes a multiplexer with inputs that include a clock signal a reset signal provided by a delay chain of the SRAM, where the multiplexer is controlled by an enable signal (RAMRO_EN). In one embodiment, the RAMRO output circuit that generates a RAMRO output signal (RAM_RO) based on the RAMRO_EN signal and an input from the delay chain of the SRAM when the RAMRO_EN signal is asserted, where the RAMRO output signal correlates to electrical characteristics of semiconductor material upon which the SRAM is located.

### BRIEF DESCRIPTION OF THE DRAWINGS

Reference is now made to the following descriptions taken in conjunction with the accompanying drawings, in which:

FIG. 1 illustrates a block diagram of a system-on-a-chip (SOC) constructed according to the principles of the disclosure;

FIG. 2 illustrates a block diagram for an example of an on-chip SRAM constructed according to principles of the disclosure;

FIG. 3 illustrates a circuit diagram of an example of an on-chip SRAM having an SRAM ring oscillator (RAMRO) constructed according to the principles of the disclosure;

FIG. 4 illustrates a block diagram for an example SOC with logic external to on-chip SRAM of the SOC, which is constructed to determine electrical characteristics of a specific portion of on-chip SRAM on SOC according to the principles of the disclosure;

FIG. 5 illustrates a timing diagram of an example of a RAMRO constructed according to the principles of the disclosure; and

FIG. 6 illustrates a flow diagram of an example of a method of operating a RAMRO carried out according to the principles of the disclosure.

### DETAILED DESCRIPTION OF THE DISCLOSURE

As noted above, it is common to place in-silicon monitoring circuitry on ICs, particularly large ICs like SOCs, in the form of a RO. The RO is typically placed on the IC at a location that is convenient, i.e., in the case of a large SOC, where there may be unused or underutilized locations on a layout of the IC or die. In some cases, the RO is advantageously placed, e.g., near a large logic block of circuitry. In this case, the RO may indicate that the silicon performance characteristics specific to the location of the large logic block are acceptable or even more than acceptable, allowing the semiconductor manufacturer to bin the specific IC based on indicated silicon performance from the RO near the large logic block. However, if the performance characteristics of silicon near other circuitry of the large IC, e.g., SOC, such as an SRAM, were slower than the performance characteristics of the silicon near the large logic block, the semiconductor manufacturer would improperly bin the IC out as being at or above acceptable performance characteristics, even when the semiconductor manufacturer should bin the IC out differently because of poorer characteristics of the silicon near the SRAM. Moreover, the SRAM provides a unique combination of SRAM bit cells, complex logic needed to write to and read from the SRAM bit cell, and, inter alia, long wires and branch loading that is unlike typical synthesized logic blocks. Thus, silicon performance characteristics for areas of the die near the SRAM can be quite different than silicon performance characteristics for areas of the die near, e.g., large logic blocks or processing units. Put another way, results from ROs located near large blocks of logic in many cases does not yield reliable and accurate information about SRAM performance located away from the large blocks of logic.

Other uses for the determination of the SRAM performance based on the RO is to identify potential design problems with the SOC or portions thereof. For example, if there are consistent performance issues from the SRAM performance determined from the RO, this information can be used to improve the design of portions of the SOC.

The disclosure provides in-silicon monitoring circuitry, e.g., a RO, physically local to RAM, e.g., SRAM, at a specific location on a die on a semiconductor wafer and a method that yields reliable and accurate information about how the SRAM will perform. The disclosed in-silicon monitoring circuitry and method allows for binning out specific dies on a wafer based on performance of the SRAM, e.g., electrical characteristics of silicon material upon which the SRAM is located on a die rather than electrical characteristics of silicon material elsewhere on the same die. Further, the disclosed in-silicon monitoring circuitry and method also provides an indication as to whether the design for the existing on-chip SRAM is adequate or if revisions to the design are needed to improve performance of the SRAM.

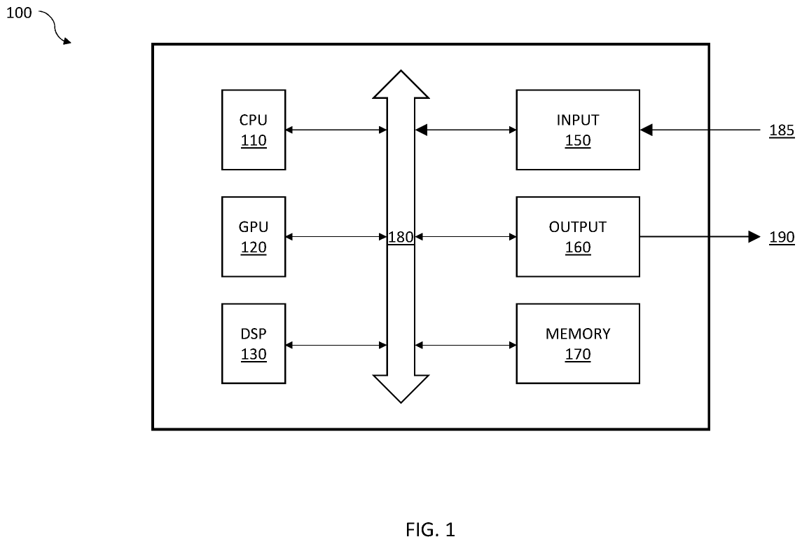

Referring to the drawings, specifically FIG. 1, a block diagram of a system-on-a-chip (SOC) 100 constructed according to the principles of the disclosure is shown. SOC 100 includes at least one CPU 110, at least one GPU 120, optionally at least one digital signal processor 130, input circuitry 150, output circuitry 160, and memory 170. Of course, in some embodiments SOC 100 can include more than one CPU 110, GPU 120, or DSP 130 or, in other embodiments, SOC 100 could omit any of CPU 110, GPU 120, or DSP 130. As depicted in FIG. 1, in some embodiments, CPU 110, GPU 120, DSP 130, input circuitry 150, output circuitry 160, and memory 170 communicate with each other over bus 180. In some embodiments, additional busses between different processing units (e.g., CPU 110, GPU 120, and DSP 130) and between different processing units (e.g., CPU 110, GPU 120, and DSP 130), input circuitry 150, output circuitry 160, and memory 170 can be employed (not shown). Memory 170 can be comprised of differing types of volatile memories (e.g., dynamic random access (DRAM) memory, SRAM memory, etc.) and/or non-volatile memories (e.g., read-only memory (ROM), erasable programmable read-only memory (EPROM), electrically erasable programmable read-only memory (EEPROM), flash memory, etc.). In some embodiments of SOC 100, memory 170 includes on-chip SRAM which includes an in-silicon monitoring circuit constructed in accordance with the principles of the disclosure as described below. Also as depicted in FIG. 1, SOC 100's input circuitry 150 accepts signals 185 externally provided to SOC 100 and SOC 100's output circuitry 160 provides signals 190 external to SOC 100.

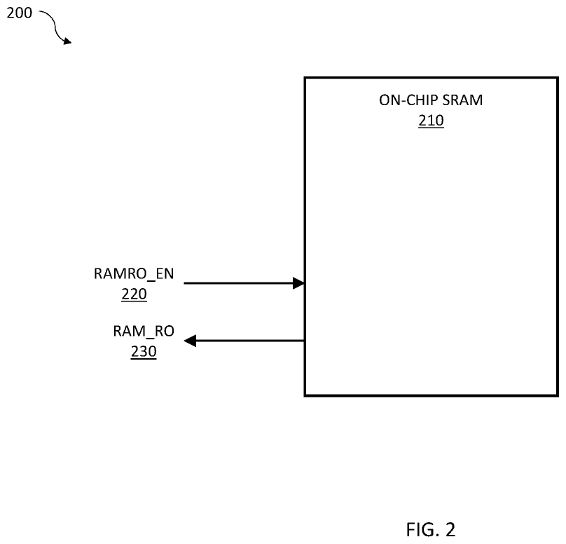

FIG. 2 illustrates a block diagram of an on-chip SRAM 200 constructed according to the principles of the disclosure. On-chip SRAM 200, in some embodiments may be a self-timed on-chip SRAM where at least one of the clock signals needed to operate the SRAM is generated internally, usually from a clock signal applied to the self-timed on-chip SRAM, e.g., on-chip SRAM 200. While not shown in FIG. 2, on-chip SRAM 200 includes conventional blocks of an SRAM, e.g., addressing decode circuitry, pre-charge circuitry, column decode circuitry, bit cell array, sense amplifiers, timing circuitry, etc. as well as interconnects (e.g., wire traces, inter-level interconnects, etc.) In some embodiments, on-chip SRAM 200 also includes (not shown) a plurality of “dummy” replica bit cells that are similar to the actual bit cells in the bit cell array of the SRAM. These replica bit cells are used to, e.g., mimic bit cell discharge and bit line pre-charge delay to be able to mimic a read operation from the bit cell array and mirror its bit line loading. As depicted in FIG. 2, an enable signal RAMRO_EN 220 is applied to on-chip SRAM 200 and an output signal RAM_RO 230 is output from on-chip SRAM 200 as will be described below.

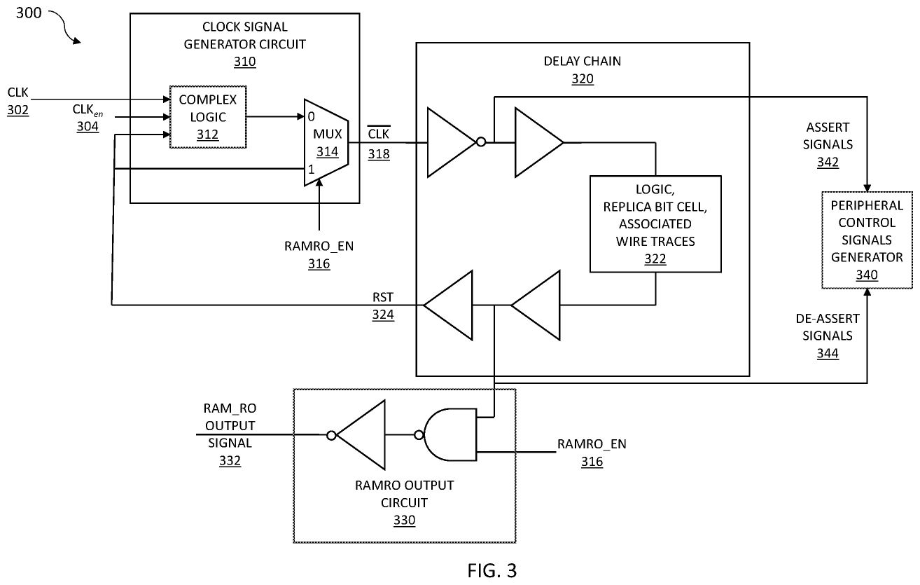

FIG. 3 illustrates a circuit diagram of an example of an on-chip SRAM, e.g., on-chip SRAM 200 of FIG. 2, having an SRAM ring oscillator (RAMRO) constructed according to the principles of the disclosure. As discussed above, this disclosure provides in-silicon monitoring circuitry, e.g., a RO, physically local to RAM, e.g., SRAM, at a specific location on a die on a semiconductor wafer and a method that yields reliable and accurate information about how the SRAM will perform, enabling binning out specific dies on a wafer based on performance of the SRAM (e.g., electrical characteristics of silicon material upon which the SRAM is located on a die) as well as an indication as to whether the design for the existing on-chip SRAM is adequate (or if revisions to the design are needed to improve performance of the SRAM). Generally speaking, the disclosed in-silicon, on-chip monitoring circuitry utilizes circuitry already present in the on-chip SRAM with very little additional circuitry to form the RAMRO. For example, the SRAM ring oscillator (RAMRO) utilizes a plurality of inverters, logic circuity, at least one replica bit cell circuit, and associated wire traces already found in the on-chip SRAM that comprise a delay chain. That is, inverters ordinarily used to distribute clock signals to portions of the on-chip self-timed SRAM are used in the delay chain of the RAMRO. Logic circuitry ordinarily used to perform functions in the on-chip SRAM are used in the delay chain. The replica bit cells described above are used in the delay chain. And the associated wire traces described above are used in the delay chain. Moreover, the delay chain of the on-chip SRAM performs as a RO, e.g., the RAMRO.

In addition to the delay chain described above, the disclosed in-silicon monitoring circuitry of the on-chip SRAM also includes a multiplexer that allows for a clock signal to be input into the on-chip SRAM for normal operation or allows for a signal exiting the delay chain to be re-input into the delay chain of the on-chip SRAM. When the multiplexer switches the signal input into the on-chip SRAM from the clock signal for normal operation of the on-chip SRAM (e.g., operating the on-chip SRAM in a “normal mode”) to the signal output from the delay chain of the on-chip SRAM (e.g., operating the on-chip SRAM in a “RAMRO mode”), a pulse count over a given amount of time for the clock signal input into the on-chip SRAM operating in the normal mode can be compared to a pulse count over the same given amount of time of the signal traveling through the delay chain of the on-chip SRAM after being re-input to the delay chain of the on-chip SRAM in the RAMRO mode (after the multiplexer switches the signal input to the on-chip SRAM to the signal output from the delay chain of the on-chip SRAM). This comparison of the pulse counts over the same given amount of time correlates to electrical characteristics of semiconductor material upon which the on-chip SRAM is located as discussed above.

For example, if the number of pulses of the given amount of time for the signal traveling through the delay chain of the on-chip SRAM in the RAMRO mode is fewer than the number of pulses of the clock signal input to the delay chain of the on-chip SRAM in the normal mode, this could indicate that the performance of the silicon local to the on-chip SRAM is less than desired. And if, e.g., this performance is less than a threshold level, the IC that includes the SRAM, e.g., SOC 100 described above, could be binned out or the design of the on-chip SRAM could be altered such that its performance is improved.

As depicted in FIG. 3 on-chip SRAM 300 includes clock signal generator circuit 310, delay chain 320, RAMO output circuit 330, and peripheral control generator 340. Clock signal generator circuit 310, includes complex logic 312 and 2-to-1 multiplexer (MUX) 314. In the normal mode described above (e.g., a SRAM read/write operation), when the RAMRO enable signal, e.g., RAMRO_EN signal 316 (similar to RAMRO_EN signal 220 of FIG. 2 as discussed above) is set low (e.g., RAMRO_EN=0) and when a primary clock signal (e.g., CLK signal 302) goes high, CLK signal 318 will be activated as will downstream delay chain 320. Further, when RST signal 324 is asserted (e.g., active at 1), CLK signal 318 will be de-asserted. In the RAMRO mode discussed above, the RAMRO enable signal, e.g., RAMRO_EN signal 316 is set high (e.g., RAMRO_EN=1) and complex logic 312 in clock signal generator circuit 310 will be gated off by RAMRO_EN signal 316. In this mode, delay chain 320 will act as an inverter style ring oscillator as RST signal 324 will be input into delay chain 320 rather than CLK signal 302.

Delay chain 320 will provide assert signals 342 to peripheral control signals generator 340 so that the self-timed on-chip SRAM have correct timing and alignment during regular memory access, (i.e., WL, COLSEL, PCHARGE, etc. signals). While FIG. 3 depicts that assert signals 342 are generated at a specific node of delay chain 320, assert signals 342 can come from any node of delay chain 320. Additionally, in some embodiments, de-assert signals 344 are also provided to peripheral control signals generator 340 to provide other correct timing and alignment during regular memory access. Delay chain 320 further includes other combinatorial logic, at least one replica bit cell, and associated wire traces 322. As discussed above, the inverters/buffer and combinatorial logic, replica bit cell(s), and associated wire traces are elements are needed for normal operation of self-timed on-chip SRAMs. Not shown in FIG. 3 are conventional portions of on-chip RAM, e.g., bit cell array, address decode circuitry, pre-charge circuitry, sense amplifiers, etc.

RAMRO output circuit 330 ensures RAM_RO output signal 332 stays low when the RAMRO enable signal is low (e.g., RAMRO_EN 316=0). This eliminates extra power consumption. In addition to RAMRO_EN signal 316, FIG. 3 depicts another input to RAMRO output circuit 330 that is generated at a specific node of delay chain 320. However, in other embodiments, this input could be generated at other nodes of delay chain 320.

In operation, self-timed on-chip SRAM 300 performs normal SRAM read/write operations in the above-described normal mode when the RAMRO enable signal, e.g., RAMRO_EN signal 316 is low, allowing a clock signal input to SRAM 300 (e.g., CLK signal 302 of FIG. 3) pass through (when a clock enable signal, e.g., CLKₑₙ signal 304 of FIG. 3 is high) to the elements of delay chain 320 which, in turn, provide proper timing signals to peripheral control signals generator 340 for normal SRAM read/write operations. However, when it is desired to determine electrical performance of the portion of the SOC, e.g., SOC 100 of FIG. 1, local to SRAM on the SOC, e.g., SRAM 200 of FIG. 2 or SRAM 300 of FIG. 3, the RAMRO enable signal, e.g., RAMRO_EN signal 316, is set high which allows for RST signal 324 to recirculate back through delay chain 320 in the above-described RAMRO mode. In the RAMRO mode, the RAMRO enable signal, e.g., RAMRO_EN signal 316, allows RAMRO output circuit 330 to output a RAMRO output signal, e.g., RAM_RO output signal 332. As discussed above, comparing a pulse count of RAM_RO output signal 322 when in RAMRO mode to a pulse count of a clock signal input into the on-chip SRAM when in normal mode will provide an indication electrical characteristics of a portion of the SOC local to the SRAM on the SOC.

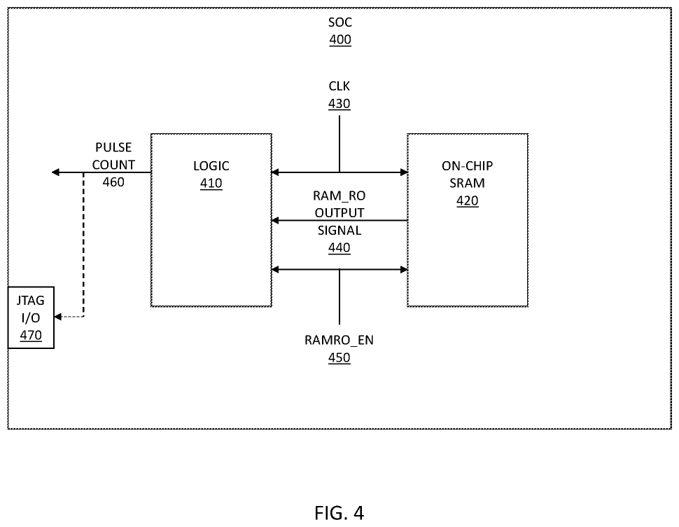

FIG. 4 illustrates a block diagram for an example SOC 400 with logic 410 external to on-chip SRAM 420 of SOC 400 constructed to determine electrical characteristics of a specific portion of on-chip SRAM 420 on SOC 400 according to the principles of the disclosure. Logic 410 external to on-chip SRAM 420 (similar to on-chip SRAM 200 of FIG. 2 or on-chip SRAM 300 of FIG. 3) on SOC 400 receives CLK signal 430 (similar to CLK signal 302 of FIG. 3) which is also input to on-chip SRAM 420. Logic 410 on SOC 400 receives RAMRO enable signal RAMRO_EN 450 (similar to RAMRO_EN signal 316 of FIG. 3 and RAMRO_EN signal 220 of FIG. 2) which is also input to on-chip SRAM 420, and RAM_RO output signal 440 (similar to RAM_RO output signal 332 of FIG. 3 and RAM_RO output signal 230 of FIG. 2). In some embodiments, pulse count signal 460 representing a count of pulses of RAM_RO output signal 440 is output from logic 410 to other portions of SOC 400 where electrical characteristics of the portion of SOC 400 local to on-chip SRAM 420 are interpreted. In other embodiments, pulse count signal 460 representing a count of pulses of RAM_RO output signal 440 is provided to JTAG I/O 470 where circuitry external to SOC 400 determines electrical characteristics of the portion of SOC 400 local to on-chip SRAM 420. Moreover, when on-chip SRAM 420 in is RAMRO mode, a peripheral control signal generator of on-chip 420 (not shown) continues to operate on-chip SRAM 420 so that pulse count signal 460 representing a count of pulses of RAM_RO output signal 440 is reflective of a normally operating on-chip SRAM (even though, while in RAMRO mode, an output of on-chip SRAM 420 will, in some embodiments, not be used).

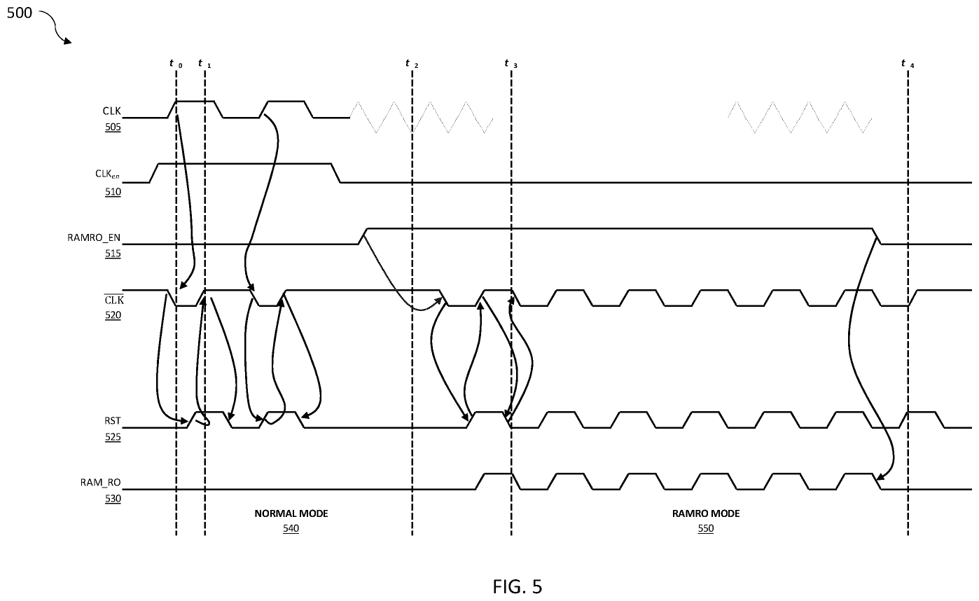

FIG. 5 illustrates a timing diagram 500 of an example of a RAMRO constructed according to the principles of the disclosure. Timing diagram 500 includes waveforms that demonstrate a timing sequence of a delay chain, e.g., delay chain 320 of FIG. 3, for both the above-described normal and RAMRO modes. Timing diagram 500 includes clock signal (CLK) 505 (similar to CLK signal 302 of FIG. 3 and CLK signal 430 of FIG. 4), clock enable signal 510 (CLKₑₙ, similar to CLKₑₙ signal 301 of FIG. 3), RAMRO enable signal 515 (RAMRO_EN, similar to RAMRO_EN signal 220 of FIG. 2, RAMRO_EN signal 316 of FIG. 3, and RAMRO_EN signal 450 of FIG. 4), CLK signal 520 (similar to CLK signal 318 of FIG. 3), reset (RST) signal 525 (similar to RST signal 324 of FIG. 3), and RAM_RO output signal 530 (similar to RAM_RO output signal 230 of FIG. 2, RAM_RO output signal 332 of FIG. 3, and RAM_RO output signal 450 of FIG. 4).

CLKₑₙ signal 510 indicates that the memory access operation (Read/Write), e.g., the above-described normal mode, occurs when CLKₑₙ signal 510 is asserted and RAMRO_EN signal 515 is de-asserted (events t₀-t₁). The above-described RAMRO mode occurs when CLKₑₙ signal 510 is de-asserted and RAMRO_EN signal 515 is asserted (event t₂-t₄). At timing events t₀-t₁, CLK signal 520 is asserted when CLK 505 is asserted. Whereas RST 525's assertion will be upon de-assertion of C̅L̅K̅ signal 520. During these periods, RAMRO_EN 515 will be de-asserted, which will keep the RAM_RO output signal 530 stays low. At timing events t₂-t₄, CLK 505 will be gated off by the RAMRO_EN 515. Asserting RAMRO_EN 515 will trigger C̅L̅K̅ signal 520 to fall at timing event t₂ (start from timing event t₃, C̅L̅K̅ signal 520 falling is triggered by RST 525 falling). After a fixed amount of delay through the delay chain 330, RST 525 will start rising. From this point, delay chain 320 has become a ring oscillator and it will keep oscillating until RAMRO_EN 515 is de-asserted (event t₄).

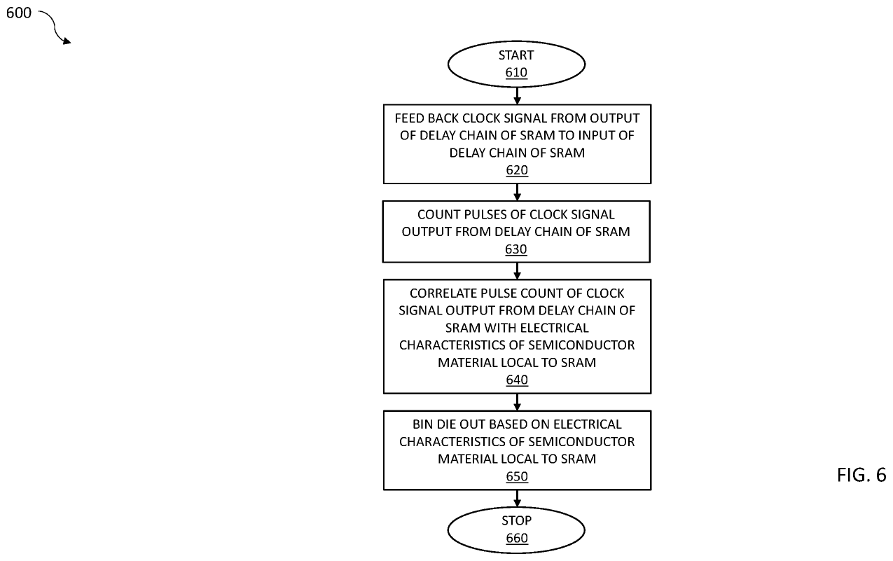

FIG. 6 illustrates a flow diagram 600 of an example of a method of operating a RAMRO carried out according to the principles of the disclosure. This method starts at step 610. At step 620, a clock signal (e.g., RST signal 324 of FIG. 3) is fed back from an output of a delay chain of a self-timed on-chip SRAM (e.g., delay chain 320 of FIG. 3) to an input of the delay chain (controlled by a multiplexer, e.g., multiplexer 314 of clock signal generator circuit 310 of FIG. 3). At step 640, a pulse count of a clock signal output from a delay chain (e.g., pulse count 460 of FIG. 4) is correlated with electrical characteristics of semiconductor material local to the on-chip SRAM (e.g., the portion of an SOC upon which the on-chip SRAM is located). At step 650, dies (e.g., SOC dies) are binned out based on the electrical characteristics of semiconductors material local to the on-chip SRAM.

In some embodiments, a library of circuit designs comprise the above-described in-silicon monitoring circuit for on-chip SRAM where the in-silicon monitoring circuit includes the above-described clock generation unit, ring oscillator, and RAMRO output circuit. In some embodiments, the clock generation unit of the library of circuit designs includes a logic function circuit with inputs that include at lease a clock signal for the SRAM, a clock enable signal, and a reset signal and a multiplexer with inputs that include an output from the logic function circuit and the reset signal where the multiplexer is controlled by RAMRO enable signal (RAMR)_EN). In some embodiments, the ring oscillator of the SRAM of the library of circuit designs comprises a delay chain which includes at least a plurality of inverters, logic circuity, at least one replica bit cell circuit, and associated wire traces, where an input to the delay chain is an output of the multiplexer of the clock generation unit, In some embodiments, the RAMRO output circuit of the library of circuit designs generates a RAMRO output signal (RAM_RO) based on the RAMRO_EN signal and an input from the delay chain where the RAMRO output signal correlates to electrical characteristics of semiconductor material upon which the SRAM is located.

In some embodiments, the library of circuit designs enable die containing the SRAM to be binned out based on the electrical characteristics of the semiconductor material upon which the SRAM is located. In some embodiments, the library of circuit designs enable alteration of a design of the on-chip SRAM based on the electrical characteristics of the semiconductor material upon which the SRAM is located.

A portion of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein. The data storage media can be part of or associated with the digital data processors or computers.

The digital data processors or computers can be comprised of one or more GPUs, one or more CPUs, one or more of other processor types, or a combination thereof. The digital data processors and computers can be located proximate each other, proximate a user, in a cloud environment, a data center, or located in a combination thereof. For example, some components can be located proximate the user and some components can be located in a cloud environment or data center.

The GPUs can be embodied on a single semiconductor substrate, included in a system with one or more other devices such as additional GPUs, a memory, and a CPU. The GPUs may be included on a graphics card that includes one or more memory devices and is configured to interface with a motherboard of a computer. The GPUs may be integrated GPUs (iGPUs) that are co-located with a CPU on a single chip. Configured or configured to means, for example, designed, constructed, or programmed, with the necessary logic and/or features for performing a task or tasks.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices. Configured or configured to means, for example, designed, constructed, or programmed, with the necessary logic and/or features for performing a task or tasks. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

What is claimed is:

1. An in-silicon monitoring circuit for an on-chip static RAM (SRAM), comprising:
a clock generation unit including:
a logic function circuit with inputs that include at least a clock signal for the SRAM, a clock enable signal, and a reset signal; and
a multiplexer with inputs that include an output from the logic function circuit and the reset signal, wherein the multiplexer is controlled by an enable signal (RAMRO_EN);
a ring oscillator of the SRAM (RAMRO) comprising a delay chain of the SRAM which includes at least a plurality of inverters, logic circuity, at least one replica bit cell circuit, and associated wire traces, wherein an input to the delay chain is an output of the multiplexer of the clock generation unit; and
a RAMRO output circuit that generates a RAMRO output signal (RAM_RO) based on the RAMRO_EN signal and an input from the RAMRO when the RAMRO_EN signal is asserted, wherein the RAMRO output signal correlates to electrical characteristics of semiconductor material upon which the SRAM is located.

2. The in-silicon monitoring circuit as recited in claim 1, further comprising a peripheral control signals generator for the SRAM.

3. The in-silicon monitoring circuit as recited in claim 2, wherein:
the delay chain of the SRAM is used as the RAMRO when the RAMRO_EN signal is asserted; and
the delay chain of the SRAM is used as a timing generator for the peripheral control signals generator when the RAMRO_EN signal is not asserted.

4. The in-silicon monitoring circuit as recited in claim 3, wherein when the delay chain is used as the RAMRO, the peripheral control signal generator continues to operate the SRAM.

5. The in-silicon monitoring circuit as recited in claim 1, wherein a count of pulses of the RAMRO output signal correlates to the electrical characteristics of the semiconductor material upon which the SRAM is located.

6. The in-silicon monitoring circuit as recited in claim 5, wherein the count of pulses of the RAMRO output signal is provided to JTAG I/O.

7. The in-silicon monitoring circuit as recited in claim 5, wherein the count of pulses is used to bin out die with the in-silicon monitoring circuit.

8. A method of determining electrical characteristics of semiconductor material upon which an SRAM on a die is located, comprising:
feeding back a clock signal from an output of a ring oscillator of the SRAM (RAMRO) to the input of the RAMRO, wherein the RAMRO comprises a delay chain of the SRAM which includes at least a plurality of inverters, logic circuity, at least one replica bit cell circuit, and associated wire traces;
counting pulses of the clock signal output from the RAMRO of the SRAM (RAM_RO output signal);
correlating the count of pulses of the clock signal output from the delay chain of the SRAM (RAM_RO output signal) with electrical characteristics of the semiconductor material upon which the SRAM on the die is located; and
binning out die based on the electrical characteristics of the semiconductor material upon which the SRAM on the die is located.

9. The method of determining electrical characteristics as recited in claim 8, wherein the clock signal from the output of the delay chain of the SRAM is fed back to the input of the delay chain of the SRAM when an enable signal (RAMRO_EN) is applied to a multiplexer with the output of the delay chain of the SRAM being an input to the multiplexer.

10. The method of determining electrical characteristics as recited in claim 9, wherein when the RAMRO_EN signal is not applied to the multiplexer, a clock signal applied to the multiplexer is passed through to the input of the delay chain of the SRAM rather than the output of the delay chain of the multiplexer.

11. The method of determining electrical characteristics as recited in claim 10, wherein the clock signal applied to the multiplexer passes through the multiplexer to the input of the delay chain of the SRAM when a clock enable signal is asserted.

12. The method of determining electrical characteristics as recited in claim 8, wherein the pulses of the clock signal output from the delay chain of the SRAM are counted when the RAMRO_EN signal is asserted.

13. The method of determining electrical characteristics as recited in claim 12, wherein the count of pulses of the clock signal output from the delay chain of the SRAM (RAM_RO) are provided to JTAG I/O on the die.

14. An integrated circuit (IC), comprising:
at least one processing unit; and
at least one static random-access memory (SRAM) communicatively coupled to the at least one processing unit, wherein the SRAM includes an in-silicon monitoring circuit, the in-silicon monitoring circuit including:
a clock generation unit comprising:
a logic function circuit with inputs that include at least a clock signal for the at least one SRAM, a clock enable signal, and a reset signal; and
a multiplexer with inputs that include an output from the logic function circuit and the reset signal, wherein the multiplexer is controlled by an enable signal (RAMRO_EN);
a ring oscillator of the SRAM (RAMRO) comprising a delay chain which includes at least a plurality of inverters, logic circuity, at least one replica bit cell circuit, and associated wire traces, wherein an input to the delay chain is an output of the multiplexer of the clock generation unit; and
a RAMRO output circuit that generates a RAMRO output signal (RAM_RO) based on the RAMRO_EN signal and an input from the delay chain when the RAMRO_EN signal is asserted, wherein the RAMRO output signal correlates to electrical characteristics of semiconductor material upon which the SRAM is located.

15. The IC as recited in claim 14, further comprising a peripheral control signals generator for the SRAM.

16. The IC as recited in claim 15, wherein:
the delay chain of the SRAM is used as the RAMRO when the RAMRO_EN signal is asserted; and
the delay chain of the SRAM is used as a timing generator for the peripheral control signals generator when the RAMRO_EN signal is not asserted.

17. The IC as recited in claim 16, wherein when the delay chain is used as the RAMRO, the peripheral control signal generator continues to operate the SRAM.

18. The IC as recited in claim 14, wherein the at least one processing unit is a central processing unit (CPU).

19. The IC as recited in claim 14, wherein the at least one processing unit is a graphics processing unit (GPU).

20. The IC as recited in claim 14, wherein a count of pulses of the RAMRO output signal correlates to the electrical characteristics of the semiconductor material upon which the SRAM is located.

21. The IC as recited in claim 20, wherein the count of pulses of the RAMRO output signal is provided to JTAG I/O.

22. The IC as recited in claim 20, wherein the count of pulses is used to bin out die with the in-silicon monitoring circuit.

23. A library of circuit designs, comprising:
a design for an in-silicon monitoring circuit for an on-chip static RAM (SRAM), wherein the in-silicon monitoring circuit includes:
a clock generation unit comprising:
a logic function circuit with inputs that include at least a clock signal for the SRAM, a clock enable signal, and a reset signal; and
a multiplexer with inputs that include an output from the logic function circuit and the reset signal, wherein the multiplexer is controlled by an enable signal (RAMRO_EN);
a ring oscillator of the SRAM (RAMRO) comprising a delay chain which includes at least a plurality of inverters, logic circuity, at least one replica bit cell circuit, and associated wire traces, wherein an input to the delay chain is an output of the multiplexer of the clock generation unit; and
a RAMRO output circuit that generates a RAMRO output signal (RAM_RO) based on the RAMRO_EN signal and an input from the delay chain, wherein the RAMRO output signal correlates to electrical characteristics of semiconductor material upon which the SRAM is located.

24. The library of circuit designs as recited in claim 23, wherein die containing the on-chip SRAM is binned out based on the electrical characteristics of the semiconductor material upon which the SRAM is located.

25. The library of circuit designs as recited in claim 23, wherein a design of the on-chip SRAM is altered based on the electrical characteristics of the semiconductor material upon which the SRAM is located.

26. An in-silicon monitoring circuit for an on-chip static RAM (SRAM), comprising:
a clock generation unit including a multiplexer with inputs that include a clock signal a reset signal provided by a delay chain of the SRAM, wherein the multiplexer is controlled by an enable signal (RAMRO_EN); and
an SRAM ring oscillator (RAMRO) output circuit that generates a RAMRO output signal (RAM_RO) based on the RAMRO_EN signal and an input from the delay chain of the SRAM when the RAMRO_EN signal is asserted, wherein the RAMRO output signal correlates to electrical characteristics of semiconductor material upon which the SRAM is located.
